(19) United States
(12) Patent Application Publication
(10) Pub. No.: US 2026/0025949 A1
(43) Pub. Date: Jan. 22, 2026

(54) WATER COOLING BLOCK FOR CRYPTOCURRENCY MINING DEVICE

(71) Applicant: CryoByte Labs Inc., West Chester, OH (US)

(72) Inventors: Ryan RAMMINGER, Mason, OH (US); Bruce LIU, Dongguan City (CN)

(21) Appl. No.: 19/275,232

(22) Filed: Jul. 21, 2025

Related U.S. Application Data
(60) Provisional application No. 63/673,834, filed on Jul. 22, 2024.

(51) Int. Cl. H05K 7/20

(52) U.S. Cl. CPC H05K 7/20272

(57) ABSTRACT

A water cooling block comprises a baseplate having an inner surface and an outer surface having a plurality of raised surfaces adapted to contact integrated circuits mounted on a hashboard, microfins arranged on the inner surface, a cover mounted to the baseplate and forming a cooling water distribution chamber therebetween. A first water port is arranged at a central location on one side plate of the cover, second and third water ports are arranged at opposite ends of the one side plate of the cover, and a water channel is arranged between other side plates of the cover and a perimeter of the cooling water distribution chamber. The water channel receives heated water from or supplies cooling water to the cooling water distribution chamber at a location distal from the first water port, and the water channel extends to each of the second and third water ports.

### FIELD OF THE INVENTION

The present invention is directed to a water cooling block which is particularly suitable for cooling a cryptocurrency mining device such as a Bitcoin mining device. The invention is also directed to a cryptocurrency mining device which includes the inventive water cooling block.

### BACKGROUND OF THE INVENTION

Since its inception in 2009, the Bitcoin cryptocurrency mining landscape has undergone remarkable growth and transformation. The introduction of specialized mining hardware called ASICs (Application-Specific Integrated Circuits) led to increased processing power and energy efficiency. However, cryptocurrency mining such as Bitcoin mining remains notorious for its high energy consumption and the significant heat that it generates. Miners use specialized hardware that operates around the clock, consuming substantial amounts of electricity and the heat generated during the mining process is a natural byproduct of the energy-intensive computations. Mining facilities typically require extensive cooling systems to manage the heat, especially in regions with warm climates.

Traditional air cooling methods often struggle to dissipate the tremendous heat generated by mining machines, which can lead to reduced efficiency and potential damage to the hardware. Water cooling is gaining popularity in the cryptocurrency mining industry as an efficient and sustainable cooling solution for the high-powered ASIC miners. Water cooling systems involve circulating water through a network of pipes or tubes to absorb the heat generated by the mining equipment. The heated water is then transferred to a cooling unit, often located outside the mining facility, where it releases the heat into other mediums for further use or into the environment. The cooled water is then recirculated back to the mining equipment to continue the cooling process.

Various water cooling systems have been implemented, ranging from water cooling kits for individual machines to cargo containers outfitted with cooling technology for 200 or more mining machines. One component that many water cooling solutions share is a water cooling block which is designed to make direct contact with the heat-producing components, such as the ASIC chips, and is equipped with one or more channels through which cooling water circulates. As the warm components come into contact with the water cooling block, the heat is transferred to the circulating water, effectively cooling the electronics. FIG. 1 shows an internal configuration of a conventional water cooling block 10, sometimes referred to as a serpentine style water block, in which the arrows show water circulation from an inlet 12 to an outlet 14 via a serpentine water flow path 16.

Although more efficient at cooling Bitcoin and other cryptocurrency miners than traditional air cooling methods, there are several shortcomings associated with the use of these conventional water cooling blocks. FIG. 2 shows a CAD model of the thermal profile of a hashboard surface interface with a conventional channel-type water cooling block using Computational Fluid Dynamics (CFD) analysis. The CFD analysis shows an average chip temperature of 54.62° C., a high chip temperature of 61.62° C., and a chip temperature range of 14.42° C. (47.2° C.-61.62° C.). The warmer temperatures are represented by darker coloring in FIG. 2. As is evident, hotspots appear on the water cooling block. Cooling is not uniform and is subpar due to the basic channel design. Water traveling through the cooling block increases in temperature as it absorbs heat, and the hotter water is less effective at cooling, resulting in the visible hot spots and uneven chip temperatures. In addition, these basic water blocks are not optimized to target the hottest parts of the hashboard, typically located toward the front middle area of the hashboard. Individual chips operating at higher temperatures are less efficient and experience more wear compared to those operating at cooler temperatures, often resulting in shorter chip lifespans, increased maintenance costs, and higher risks of failure.

Accordingly, a need exists for improved technology for cooling cryptocurrency mining devices such as Bitcoin mining devices.

### SUMMARY OF THE INVENTION

Accordingly, it is an object of the invention to provide an improved water cooling block which is suitable for use with cryptocurrency mining devices, including, but not limited to, Bitcoin mining devices.

In one embodiment, therefore, the invention is directed to a water cooling block adapted for cooling a plurality of integrated circuits on a cryptocurrency mining hashboard. The water cooling block comprises (a) a baseplate having an inner surface and an outer surface, the outer surface having a plurality of raised surfaces adapted to contact integrated circuits mounted on a hashboard, (b) microfins arranged on a majority of the inner surface, (c) a cover mounted to the baseplate and comprising a top plate and side plates, the top plate and the baseplate forming a cooling water distribution chamber therebetween, the cooling water distribution chamber containing the microfins therein, (d) a first water port arranged at a central location on one side plate of the cover, the first water port being in fluid communication with the cooling water distribution chamber for supplying cooling water thereto or receiving heated water therefrom, (e) second and third water ports arranged at opposite ends of the one side plate of the cover, and (f) a water channel arranged between the side plates of the cover other than the one side plate and a perimeter of the cooling water distribution chamber to receive heated water from or supply cooling water to the cooling water distribution chamber at a location distal from the first water port, wherein the water channel extends to each of the second and third water ports.

In another embodiment, the invention is directed to a cryptocurrency mining device. The cryptocurrency mining device comprises a hashboard having a plurality of application-specific integrated circuits mounted thereon, and the water cooling block of the invention mounted on the hashboard with the plurality of raised surfaces on the outer surface of the baseplate in contact with the integrated circuits.

In yet additional embodiments, the invention is directed to methods for cooling a cryptocurrency mining device with use of the water cooling block of the invention. In one embodiment, the method comprises supplying cooling water to the first water port and removing heated water from the second and third water ports. In another embodiment, the method comprises supplying cooling water to the second and third water ports and removing heated water from the first water port.

The water cooling block of the invention is advantageous in providing more uniform cooling of an underlying surface such as a hashboard of a cryptocurrency mining device. As a result, the mining device exhibits a lower average chip temperature and more uniform chip temperatures across the mining device. These improvements allow more efficient mining, longer machine lifespan, lower maintenance costs and downtime, and hotter outlet water which can be used for a wide range of purposes.

These and additional advantages and objects of the invention will be more fully apparent in view of the following detailed description.

### BRIEF DESCRIPTION OF THE DRAWINGS

The following detailed description will be more fully understood in view of the drawings in which:

FIG. 1 is a schematic representation of the internal configuration of a conventional water cooling block;

FIG. 2 shows a CAD model of the thermal profile of a hashboard surface interface with a conventional channel-type water cooling block using Computational Fluid Dynamics (CFD) analysis;

FIG. 3 is top perspective view of one embodiment of a water cooling block of the invention;

FIG. 4 is a bottom plan view of one embodiment of a water cooling block of the invention, showing the outer surface of the baseplate;

FIG. 5 is a top plan view of one embodiment of a water cooling block of the invention;

FIG. 6 is a top plan view of microfins arranged on a majority of the inner surface of the baseplate in one embodiment of the invention;

FIG. 7 is a cross-sectional view of the baseplate and microfins taken along line A-A of FIG. 6;

FIG. 8 is an enlarged view of the cross-sectional area B in FIG. 7;

FIG. 9 is an exploded side perspective view of another embodiment of the water cooling block of the invention, showing the baseplate, microfins, and the cover;

FIG. 10 is a plan view of one edge of the microfin arrangement shown in FIG. 9;

FIG. 11 is an enlarged view of the edge area C in FIG. 10;

FIG. 12 is a plan view of another edge of the microfin arrangement shown in FIG. 9;

FIG. 13 is an enlarged view of the edge area D in FIG. 12;

FIG. 14 is a plan view of the bottom, inner side of the cover of an embodiment of the water cooling block of the invention;

FIG. 15 is a perspective view of the bottom, inner side of the cover of FIG. 14 in an embodiment of the water cooling block of the invention;

FIG. 16 is a front plan view of the cover of FIG. 14 in an embodiment of the water cooling block of the invention;

FIG. 17 is a side plan view of the cover of FIG. 14 in an embodiment of the water cooling block of the invention;

FIG. 18 shows a CAD model of the thermal profile of a hashboard surface interface combined with an embodiment of the water cooling block according to the invention using CFD analysis;

FIG. 19 is a plan view of a top of a hashboard having a plurality of application-specific integrated circuits mounted thereon for inclusion in a cryptocurrency mining device according to the invention;

FIG. 20 is a top view of a cryptocurrency mining device comprising a hashboard and a water cooling block mounted on the hashboard according to the invention;

FIG. 21 is a perspective partial cross-sectional view of the bottom, inner side of the cover and of the microfins in another embodiment of the water cooling block of the invention, showing the first water port, portions of the converging channels, and microfins;

FIG. 22 is a plan cross-sectional view of the bottom, inner side of the cover and of the microfins in the embodiment of the water cooling block of FIG. 21;

FIG. 23 is a perspective cross-sectional view of the bottom, inner side of the cover and of the microfins in the embodiment of the water cooling block of FIG. 21; and

FIG. 24 is an enlarged view of a corner area of the bottom, inner side of the cover and microfins of FIG. 23.

The elements and views in the figures are illustrative only and are non-limiting of the claimed invention.

### DETAILED DESCRIPTION

The following detailed description describes various features, elements and aspects of embodiments of the invention. While the general inventive concepts are susceptible of embodiment in many different forms, described herein in detail are specific embodiments of the invention, with the understanding that the present disclosure is to be considered as an exemplification of the principles of the general inventive concepts. Accordingly, the general inventive concepts are not intended to be limited to the specific embodiments illustrated and described herein.

The terminology as set forth herein is for description of the embodiments only and should not be construed as limiting the disclosure as a whole. Unless otherwise specified, “a,” “an,” “the,” and “at least one” are used interchangeably. Furthermore, as used in the description and the appended claims, the singular forms “a,” “an,” and “the” are inclusive of their plural forms, unless the context clearly indicates otherwise. To the extent that the term “includes” or “including” is used in the description or the claims, it is intended to be inclusive of additional elements or steps, in a manner similar to the term “comprising” as that term is interpreted when employed as a transitional word in a claim. Furthermore, to the extent that the term “or” is employed (e.g., A or B), it is intended to mean “A or B or both.” When the “only A or B but not both” is intended, then the term “only A or B but not both” is employed. Thus, use of the term “or” herein is the inclusive, and not the exclusive use. When the term “and” as well as “or” are used together, as in “A and/or B” this indicates A or B as well as A and B.

Throughout this specification, when a range of values is defined with respect to a particular characteristic of the present invention, the present invention relates to and explicitly incorporates every specific subrange therein. Additionally, throughout this specification, when a group of features is defined with respect to a particular characteristic of the present invention, the present invention relates to and explicitly incorporates every specific subgroup therein. Any specified range or group is to be understood as a shorthand way of referring to every member of a range or group individually as well as every possible subrange or subgroup encompassed therein.

The devices described herein may comprise, consist of, or consist essentially of the essential elements, respectively, as described herein, as well as any additional or optional elements, respectively, described herein.

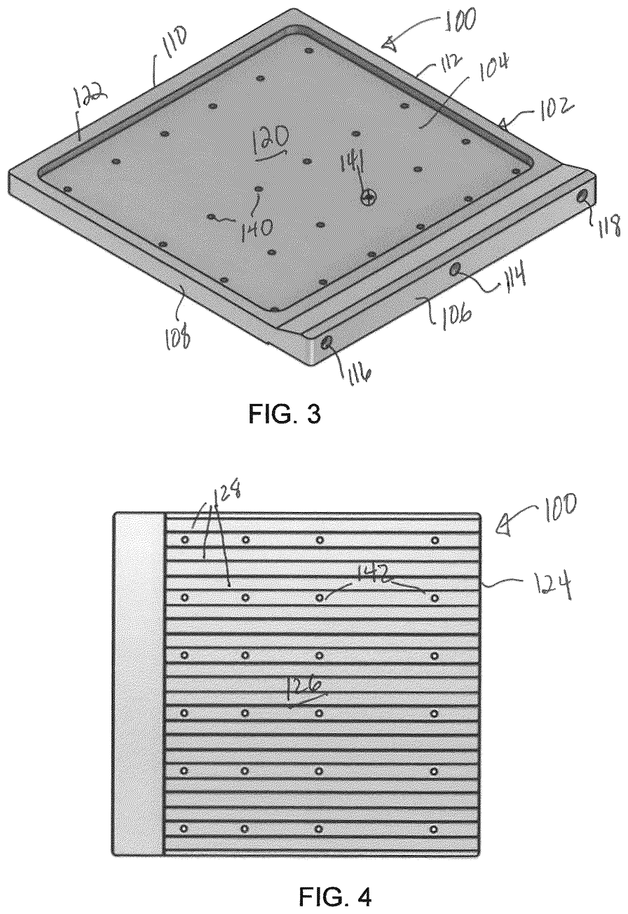

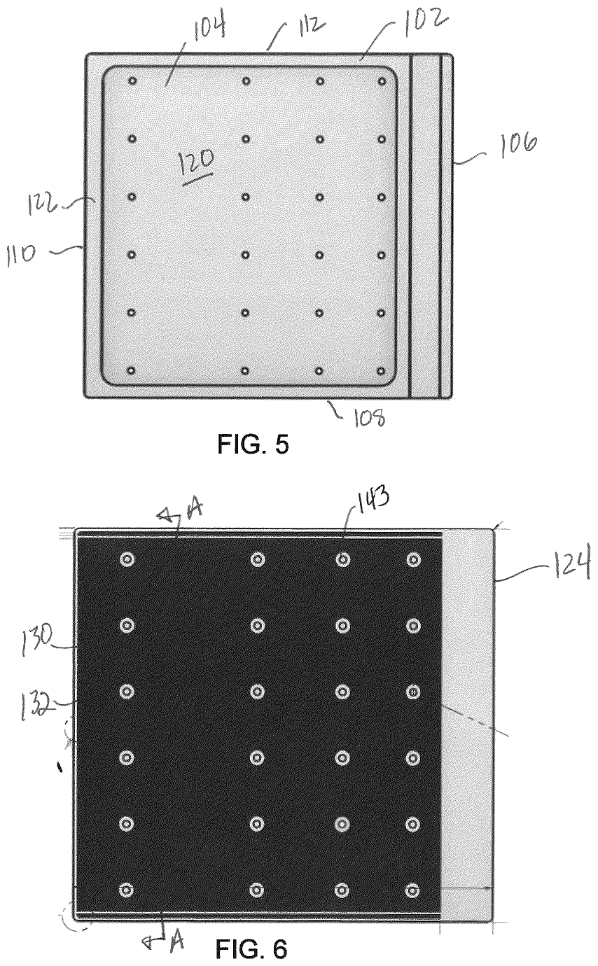

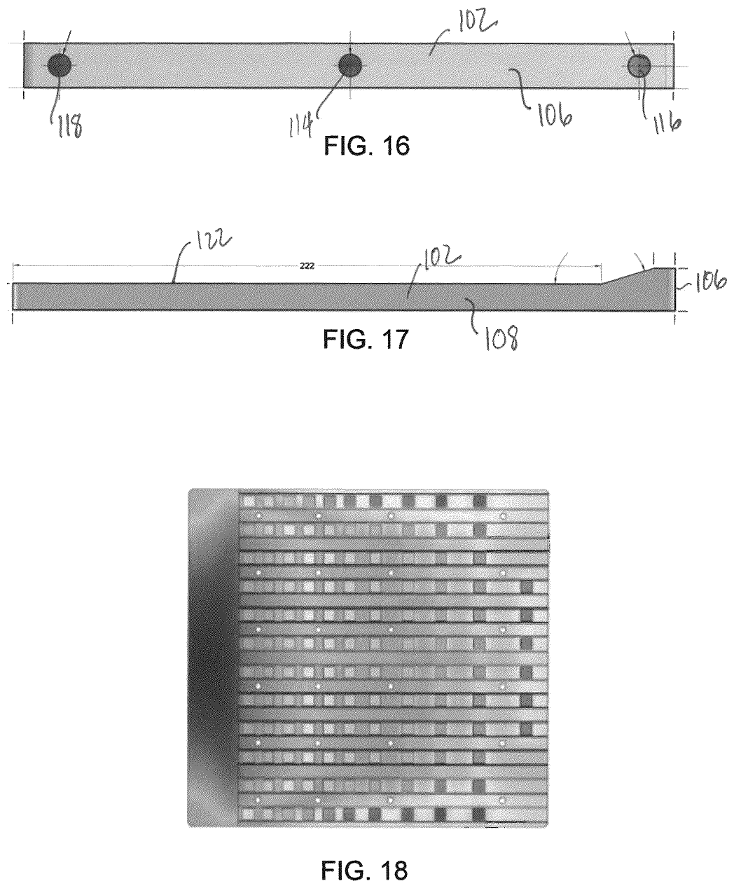

The water cooling block of the invention is comprised of a baseplate, microfins, a cover, first, second and third water ports, and a water channel. These elements combine to provide improved cooling to a mining device on which the water cooling device can be mounted. FIG. 3 shows a top perspective view of one embodiment of the water cooling block 100 according to the invention. The cover 102 is shown in FIG. 3 and also in FIG. 5 and comprises a top plate 104, and side plates 106, 108, 110 and 112. FIGS. 16 and 17 provide front and side views of the cover 102. While the cover, and the water cooling block, shown in the figures have a generally rectangular footprint, more particularly, a generally square footprint, the water cooling block may have any overall footprint configuration as desired. In a specific embodiment, the water cooling block footprint is adapted to mirror the configuration of a surface to which cooling is to be provided.

In a specific embodiment as shown in FIG. 3, the top 104 of the cover 102 includes a vertically depressed area 120 over a majority of its surface, and the vertically depressed area 120 is surrounded with a vertically higher perimeter area 122. As will be discussed in further detail below, the area 120 reduces the height of a cooling water distribution chamber located below the area 120.

As also shown in FIG. 16, the front side plate 106 of the cover is provided with a centrally located first water port 114 for introducing cooling water into or removing cooling water from the water cooling block. The front side plate 106 is also provided with second and third water ports 116 and 118, arranged on opposite sides of the first water port 114, at opposite distal ends of the front side. The flow of cooling water through the water cooling block may be arranged from the first water port 114 acting as a water inlet to the second and third water ports 116 and 118 acting as water outlets, or from the second and third water ports 116 and 118 acting as water inlets to the first water port 114 acting as a water outlet. The flow of water will be further described in detail below. By locating the first water port at a central location along the length of the front side plate 106, between two opposite corners of the front side plate, and the second and third water ports on opposite sides of the first water port 114, optimal distribution of cooling water is made through the cooling water distribution chamber. For example, when cooling water flows through the water cooling block from the first water port 114 acting as a water inlet to the second and third water ports 116 and 118 acting as water outlets, cooling water is initially distributed to an area of the water cooling block that is typically adjacent a heat dense area of an underlying hashboard which generates the most heat during mining operations, i.e., the front middle area. Hotspots as shown in FIG. 2 are significantly reduced or eliminated.

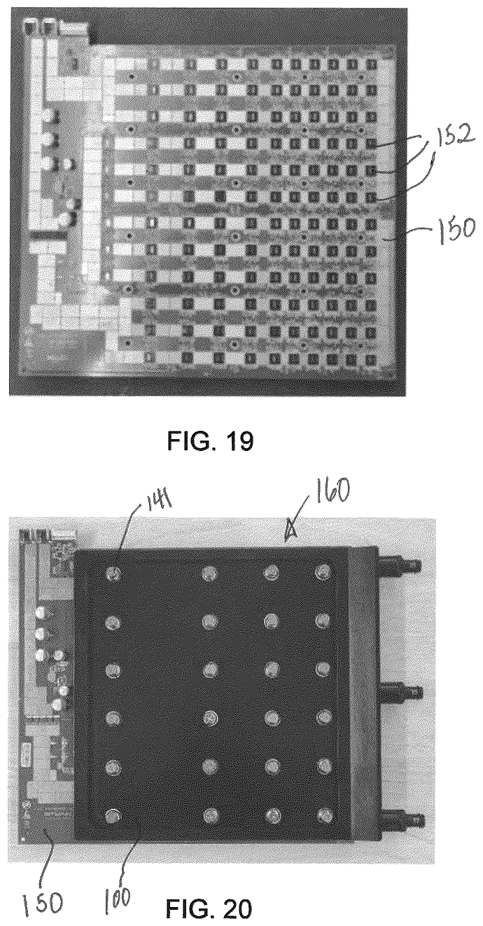

FIG. 4 provides a bottom plan view of the water cooling block 100, showing the baseplate 124. As shown in FIG. 4, the outer surface 126 of the baseplate 124 includes a plurality of raised surfaces 128 adapted to contact integrated circuits mounted on a hashboard or other mining device to provide heat transfer surfaces for contacting the circuits and removing heat from such circuits and transferring the heat to cooling water flowing through the cooling block. While the raised surfaces may be of any configuration desired, heat transfer can be increased if the raised surfaces mirror the arrangement of integrated circuits mounted on the hashboard of a mining device with which the water cooling block is intended for use. Therefore, the plurality of raised surfaces 128 may range in number from, for example, 3 to 20. As a cryptocurrency mining device such as a Bitcoin mining device typically contains circuit boards mounted in spaced rows or columns spanning a width of the hashboard, such as shown in FIG. 19, in a specific embodiment, the baseplate outer surface 126 has correspondingly spaced raised rows or columns 128 spanning a width of the baseplate and adapted for contact with such mounted circuit boards, as shown in the figures. In a more specific embodiment, the outer surface has 12 such raised surfaces in the form of rows or columns 128 spanning a width of the baseplate.

The baseplate may be formed of any desired thermally conductive material that facilitates heat transfer from an outside heat source to cooling water flowing through the water cooling block. In a specific embodiment, the baseplate is formed of aluminum or copper. Similarly, the cover may be formed of any desired thermally conductive material. However, since the cover is not in contact with the mining device in use, the cover may be formed of less thermally conductive materials, if desired. In one embodiment, the cover is formed of aluminum or copper, while in another embodiment, the cover is formed of plastic. Other materials may be employed as desired for one or more elements of the water cooling block.

FIG. 6 provides a top view of one embodiment of the baseplate 124 from the side opposite the outer surface. As shown, microfins 132 are arranged on a majority, i.e., greater than 50%, or in specific embodiments, greater than about 60%, 70%, 80% or 90%, of the inner surface 130 of the baseplate 124. The microfins may be manufactured integral with the baseplate, for example as shown in FIGS. 6-8, using skiving, extruding, CNC milling, or other techniques known in the art to produce the microfins. Alternatively, the microfins may be provided as a separately manufactured component and arranged on the inner surface 130 of the baseplate, as shown, for example in FIGS. 9-13. In either case, the microfins are formed of thermally conductive material in order to facilitate the heat exchange from the mining device from the baseplate to the cooling water. In one embodiment, the microfins are formed of aluminum or copper

The microfins increase the available cooling surface area of the water block, creating more contact between the thermally conductive material of the base plate and microfins, and the cooling water, resulting in increased heat transfer. While the size of the microfins may vary, in specific embodiments, the microfins have a height from the underlying inner surface of the baseplate of from about 1 mm to about 4 mm, from about 1 mm to about 3 mm, or from about 1 to about 2 mm, and a width of from about 0.25 mm to about 4 mm, from about 0.5 mm to about 3 mm, or from about 0.5 to about 2 mm. In additional specific embodiments, the microfins may be spaced from one another by a distance of from about 0.25 mm to about 3 mm, from about 0.25 mm to about 2 mm, or from about 0.25 mm to about 1 mm.

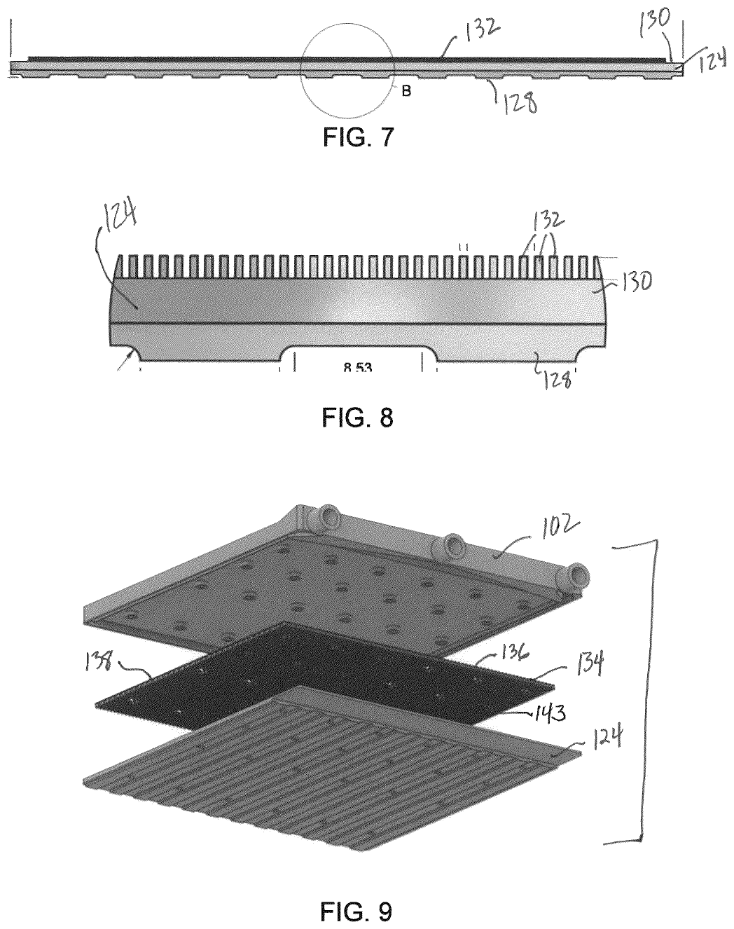

FIG. 7 provides a cross-sectional view of the baseplate 124 and microfins taken along line A-A in FIG. 6, and FIG. 8 provides an enlarged view of the encircled area B in FIG. 7. The microfins are arranged in spaced rows, with each row containing spaced microfins along the length of the baseplate inner surface. In this specific embodiment, the microfins are arranged in parallel in two directions 90° from one another. In the specific embodiment as shown in FIGS. 7 and 8, the microfins each measure approximately 1.5 mm high and 0.5 mm wide with 0.5 mm spacing both along and between rows. It is appreciated that other microfin dimensions and arrangements are equally within the scope of the water cooling block of the invention.

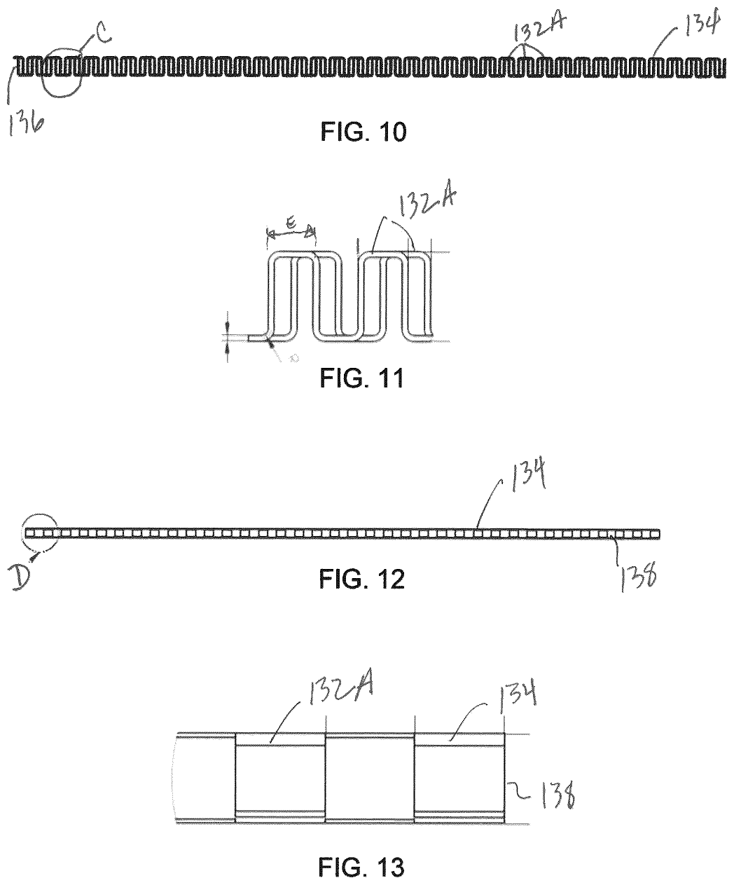

For example, in the embodiment shown in FIGS. 9-13, the microfins 132A are provided in a component 134 which is manufactured separately from the baseplate 124. The component 134 is arranged between the baseplate 124 and the cover 102 in a manner as illustrated in the exploded view of FIG. 9. Once assembled, the cover 102 and baseplate 124 are joined to one another in a water-tight manner with the component 134 therebetween to arrange the microfins in the cooling water distribution chamber formed by the cover and baseplate. FIG. 10 is a plan view of the front edge 136 of the microfin component 134 shown in FIG. 9, while FIG. 11 is an enlarged view of the edge area C in FIG. 10. FIG. 12 is a plan view of a side edge 138 of the microfin arrangement shown in FIG. 9, and FIG. 13 is an enlarged view of the edge area D in FIG. 12. In this embodiment, the microfins 132A have a lanced, open configuration, and rows of microfins are offset from one another. As shown, the microfins 132A are arranged in parallel rows in a manner wherein the fin openings are offset between microfins of adjacent rows. In a specific embodiment, the lanced microfins have a height of about 3 mm, an extension “E” as shown in FIG. 11 of about 1.5 mm to about 2 mm, and a width of about 2 mm to about 3 mm, and are offset between rows by about 0.5 to about 1 mm. Again, it is appreciated that other microfin dimensions and arrangements are equally within the scope of the water cooling block of the invention.

As shown in FIG. 9, the microfin component 134 is sandwiched between the cover and the baseplate. In a specific embodiment, the component 134 may be integrated with the baseplate or cover, for example, by brazing or soldering. The lanced offset microfins of this embodiment are particularly advantageous for cooling move evenly and cooling more effectively than solid microfins when the water cooling block is connected with a mining hashboard. Additionally, the lanced offset microfins require less power to pump water through the cooling block than solid microfins, are relatively easy to mass produce, and are lighter in weight than solid microfins.

The cover 102 and baseplate 124 are assembled in a water-tight arrangement using any suitable technique. For example, the baseplate and cover may be assembled in a water-tight manner with connectors, for example, screws, and sealing gaskets. In another embodiment, the baseplate and cover are assembled in a water-tight manner by brazing or soldering. The assembled cover and baseplate form a cooling water distribution chamber in the space therebetween, with the microfins contained in the cooling water distribution chamber. As the cooling water circulates through the chamber, contacting the baseplate and the microfins, the water absorbs heat transferred from a mining device with which the baseplate is in contact, effectively cooling the underlying mining device on which the water cooling block is mounted.

In one embodiment, the invention is directed to a cryptocurrency mining device including a water cooling block as described. The water cooling block may include means for mounting the block on a mining device. For example, the mining device may include connectors, for example mounting screws 141, one of which is shown in FIG. 3, and optionally springs, which may be positioned to extend through aligned through-holes 140 in the cover, through holes 143 in the cooling water distribution chamber, and through-holes 142 in the baseplate. The connectors suitably extend further to allow mounting of the water cooling block on a mining device, for example a mining device hashboard 150 containing a plurality of application-specific integrated circuits, i.e., chips, 152 as shown in FIG. 19, having similarly aligned receiving holes for the connectors. FIG. 20 shows such a cryptocurrency mining device 160 comprising a water cooling block 100 of the invention mounted on the mining device hashboard 150.

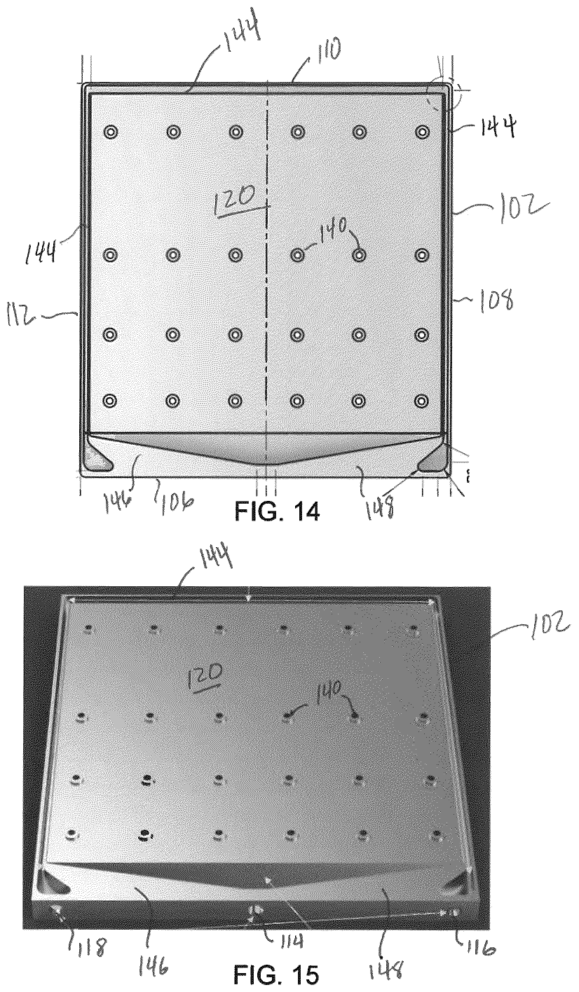

FIGS. 14 and 15 provide inverted views of one embodiment of the cover 102 of the water cooling block, showing the bottom, inner side of the cover. The vertically depressed area 120 which extends over a majority of the outer surface of the cover reduces the height of the cooling water distribution chamber formed between the cover and the baseplate and thereby aids distribution of the water through the chamber. Additionally, the vertically higher perimeter area 122 on the outer surface of the cover surrounding the area 120 correspondingly forms a water channel 144 at the perimeter of the inverted cover (on the bottom, inner side of the cover). As shown, the water channel 144 is arranged between the side plates 108, 110 and 112 of the cover, i.e., the side plates other than side plate 106 at which the first, second and third water ports are located, and a perimeter area of the cooling water distribution chamber.

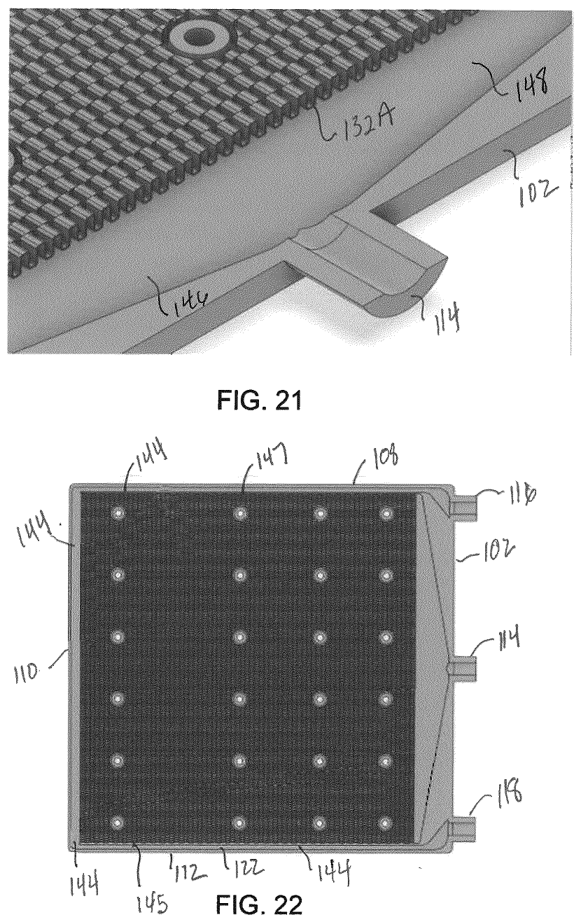

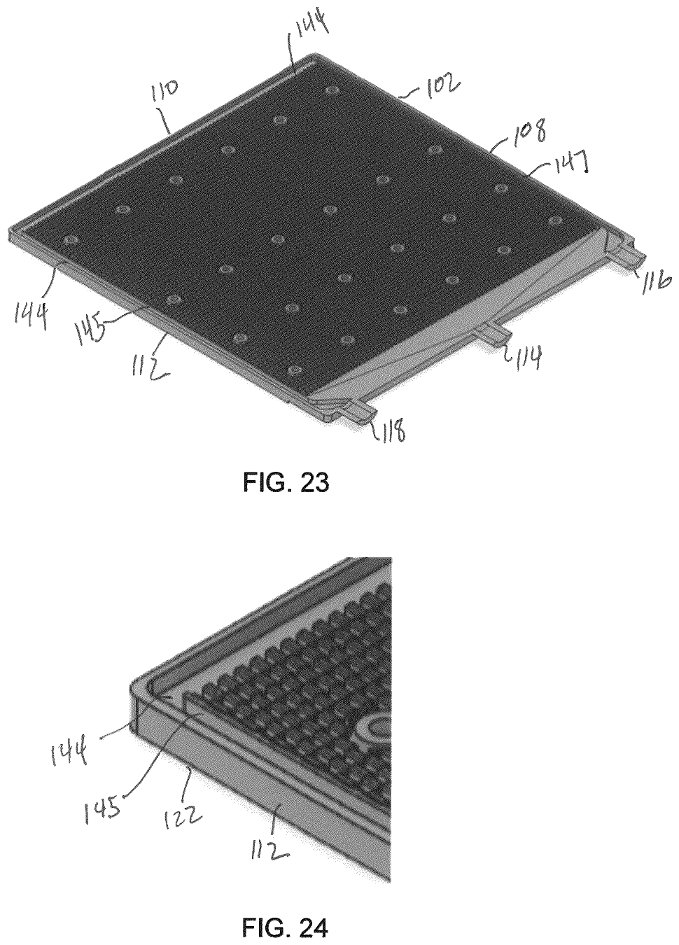

FIGS. 21-24 provide inverted views of another embodiment of the cover 102 of the water cooling block, showing the bottom, inner side of the cover, and lanced microfins 132A arranged in the cooling water distribution chamber. As best shown in FIG. 24, the water channel 144 is separated from fluid communication with the perimeter of the cooling water distribution chamber which is adjacent the side 112 of the cover by a wall 145. The water channel 144 is similarly separated from fluid communication with the perimeter of the cooling water distribution chamber which is adjacent the side 108 of the cover by a wall 147. As a result, water flows through the entire length of the cooling water distribution chamber between the side 106 with the first water port and the portion of the water channel 144 along the side 110, and therefore between opposite sides of the cooling water distribution chamber.

In the specific embodiment of FIGS. 22-24, the water channel 144 has a vertical height greater than the vertical height of the cooling water distribution chamber. However, in other embodiments, the water channel 144 has a vertical height substantially equal to the vertical height of the cooling water distribution chamber. As shown specifically in FIGS. 15 and 22, the water channel 144 extends to each of the second and third water ports 116 and 118, facilitating flow of the heated cooling water between the water channel along the side 110 and the second and third water ports 116 and 118. This fluid communication of the water channel 144 with the dual water ports arrangement, together with the centrally located first water port, allows for improved heat exchange and equalizes pressure inside the water block, leading to even water flow over all areas of the cooling water distribution chamber and optimum outlet flow of the heated cooling water.

Suitably, the channel may be positioned in the underside of the higher perimeter area 122 in the cover 102. In one embodiment, the water channel is machined into the perimeter area of the cover. Optionally, microfins may be arranged in the channel, for example, under the higher perimeter area, if desired, further increasing surface area for heat exchange and creating a greater cooling effect.

The first water port 114 may be in direct fluid communication with the cooling water distribution chamber if desired. However, in a specific embodiment, the cover 102 further comprises on its inner surface converging channels 146, 148 arranged adjacent the first water port 114. The converging channels 146, 148 converge from the first water port 114 to their distal ends and are adapted to flatten a stream of cooling water supplied from the first water port for distribution to the cooling water distribution chamber across the front side 106 of the water cooling block. As evident from FIGS. 15, 22 and 23, the converging channels 146, 148 extend from the central location where the first water port 114 is located towards, but are not in fluid communication with, the second and third water ports 116 and 118. The converging channels are designed to take incoming cooling water from the centrally located first water port 114 and flatten it across the microfinned cooling water distribution chamber to equally distribute the cooling water across the cooling water distribution chamber (and underlying hashboard in use), leading to more uniform temperatures across the chamber (and underlying hashboard). The convergences of channels 146 and 148 compress the stream of cooling water as it enters the channels from the first water port 114, typically in the form of a round pipe, to form the cooling water into a rectangular cross-sectional flow as it enters the cooling water distribution chamber containing the microfins. In a more specific embodiment, the converging channels compress the cooling water into a flowing stream having a height of about 1 mm to about 5 mm, or, more specifically, having a height of about 1 mm to about 3 mm, or, even more specifically, having a height of about 1.5 mm, as it enters the microfin-containing cooling water distribution chamber.

Thus, in one embodiment in cooling a cryptocurrency mining device, cooling water is supplied to the first water port 114. When the converging channels 146 and 148 are provided, they compress the stream of cooling water as it enters the channels from the first water port 114 to form the cooling water into a rectangular cross-sectional flow as it enters the cooling water distribution chamber containing the microfins. The cooling water flows from side 106 through the cooling water distribution chamber towards side 110 and exits the cooling water distribution into the channel 144 extending along the side 110. The hot water is then distributed to both of the water ports 116 and 118 to exit the water cooling block.

In the embodiment in which the water cooling block has a rectangular footprint as shown in the drawings, the water channel 144 has a generally C-shape as it extends along the perimeter of walls 108, 110 and 112 between the second and third water ports 116 and 118. When the first water port 114 is used as a water inlet, the water channel along the side wall 110 allows the flattened water to exit from the rows of microfins in the cooling water distribution chamber to expand and reform into skinny streams of hot water. The hot water then flows via the channel 144 to the second and third water ports 116 and 118 which then act as hot water outlets. When the height of the water channel is greater than the height of the cooling water distribution chamber, the water has more space to expand as it exits the cooling water distribution chamber into the water channel, requiring less pressure, and therefore less power, to pump the hot water back to the water outlets. In contrast, when only one water outlet is used in combination with a single water inlet, pressure differences through the water distribution chamber lead to uneven flow, inconsistent cooling and the presence of undesirable hotspots.

FIG. 18 shows a CAD model of the thermal profile of a hashboard surface interface using CFD analysis when the hashboard is combined with a water cooling block according to an embodiment of the invention including microfins as shown in FIGS. 6-8, with the first water port 114 used as a cooling water inlet and second and third water ports 116 and 118 used as hot water outlets. A comparison of FIG. 18 with the CFD analysis of the thermal profile of a hashboard surface interface combined with the conventional water cooling block in FIG. 2 easily demonstrates that the inventive water cooling block provides more even and effective cooling and avoids damaging hotspots.

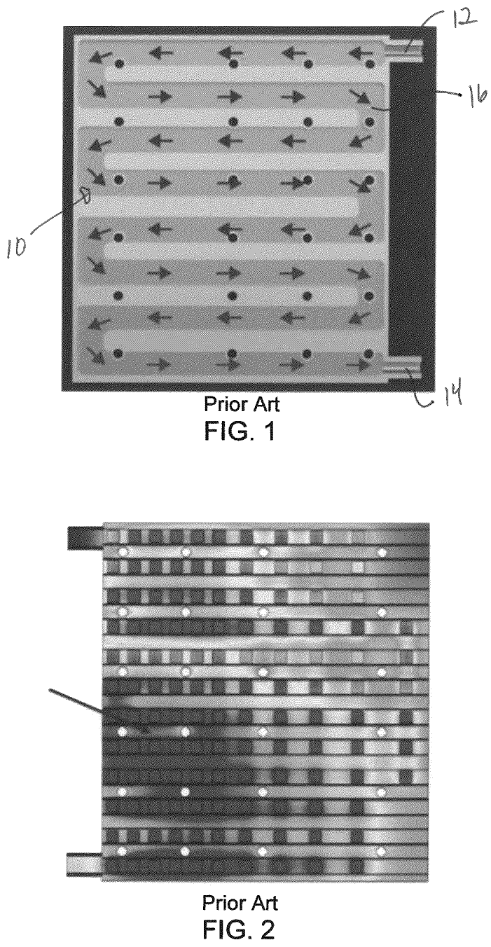

More specifically, the CFD analysis showed an average chip temperature of 47.86° C., a high chip temperature of 51.82° C., and a chip temperature range of 8.56° C. (43.26° C.-51.82° C.), all of which are significant improvements over the temperatures which result from a similar analysis of a conventional water cooling block as shown in FIGS. 1 and 2. In more detail, the water cooling block of the invention produced average chip temperatures that are 6.76° C. below that of the conventional water cooling block. Based on the temperature and power data from a 2021 Braiins research paper (braiins.com/blog/impact-of-temperature-on-efficiency-of-antminer-s19-models), this equates to an estimated energy savings of 131.82 watts per miner. Depending on the miner's cost of power and assuming a 98% uptime (industry average), a miner can expect to save between $34.22-$171.12 per device per year through reduced energy usage. Additionally, since power consumption is reduced by approximately 2.7%, less greenhouse gas is emitted into the atmosphere.

The water cooling block of the invention also showcases a high chip temperature of only 51.82° C. as compared with the described conventional water cooling block's 61.62° C., a 9.8° C. difference. The CFD analysis showed that 77.8% (98 out of 126) of the chips of a hashboard used with the conventional water cooling block operate at a higher temperature than the highest chip temperature on the hashboard when combined with the inventive water cooling block. As a result, the inventive cooling block is therefore able to extend the lifespan of the chips, and consequently the mining device, and reduce the likelihood of maintenance downtime owing to the optimal and lower temperature operation and reduced thermal stress.

In another method according to the invention, the second and third water ports 116 and 118 are used as cooling water inlets, while the first water port 114 serves as an outlet for hot water. More specifically, cooling water from ports 116 and 118 flows from the ports to side 110 of the water cooling block in the channel 144 along the sides 108 and 112 and is delivered to the cooling water distribution chamber from the channel 144 along the extent of the side 110. The heated water then exits the cooling water distribution chamber and is removed from the water cooling block through water port 114. This allows a “reverse” of the flow of the coolant water from that described previously, forcing the cool water to flow from side 110 of the water cooling block towards the side 106.

Although uncommon, when this reverse flow is combined with a cooling technique called “hybrid cooling,” which uses both water and air to cool a mining device, different cooling results can be achieved, often resulting in slightly cooler chip temperatures. The ability to reverse the coolant flow direction by changing the ports to be inlets or outlets or reversing the pump flow direction is yet another advantage of the invention.

Conventional water cooling blocks with a cooling water flow as shown in FIG. 1 are limited in changing the flow direction because they only have one inlet and one outlet. This means that a change in the flow direction only changes cooling on a vertical basis, which has limited benefit. In contrast, the inventive water cooling block moves water evenly through the cooling water distribution chamber on a horizontal basis, and reversing this flow can prove to be very advantageous when combined with hybrid cooling, since air is also moving on a horizontal basis. For example, using these two cooling mediums in a method in which water moves through the cooling water distribution chamber from back to front, i.e., from side 110 to side 106, and air moves from front to back, i.e., from side 106 to side 110, creates a crossflow of cooling, further eliminating hotspots and reducing overall chip temperatures. Therefore, the water cooling block as describe provides the ability to optimize the cooling configurations based on variable designs.

Lastly, the inventive water cooling block is able to operate using a hotter water inlet coolant and can produce a higher water outlet temperature, all while staying within the safe operating limits of the mining device. This means mining devices in warmer climates can be cooled more efficiently. The ability to use relatively warmer inlet cooling water is very advantageous in warm environments where dry coolers and water cooling towers often struggle to provide sufficiently low temperature inlet water. This process is normally referred to as “hot water cooling.” Because of the gains in efficiency from the inventive water block, a significantly hotter inlet water temperature can be used as compared with conventional water cooling blocks. Moreover, the heat from the cooling water can be reused in a wider range of potential applications. This improvement will allow cryptocurrency mining to expand to new geographic locations and to maximize economic value.

While the present application has been illustrated by the description of embodiments thereof, and while the embodiments have been described in considerable detail, such descriptions are not intended to restrict or in any way limit the scope of the appended claims to such detail. Additional advantages and modifications will readily appear to those skilled in the art. Therefore, the invention, in its broader aspects, is not limited to the specific details, the representative methods or compositions, or illustrative examples shown and described. Accordingly, departures may be made from such details without departing from the spirit or scope of the general inventive concept.

1. A water cooling block adapted for cooling a plurality of integrated circuits on a cryptocurrency mining hashboard, the water cooling block comprising
(a) a baseplate having an inner surface and an outer surface, the outer surface having a plurality of raised surfaces adapted to contact integrated circuits mounted on a hashboard,
(b) microfins arranged on a majority of the inner surface;
(c) a cover mounted to the baseplate and comprising a top plate and side plates, the top plate and the baseplate forming a cooling water distribution chamber therebetween, the cooling water distribution chamber containing the microfins therein;
(d) a first water port arranged at a central location on one side plate of the cover, the first water port being in fluid communication with the cooling water distribution chamber for supplying cooling water thereto or receiving heated water therefrom;
(e) second and third water ports arranged at opposite ends of the one side plate of the cover; and
(f) a water channel arranged between side plates of the cover other than the one side plate and a perimeter of the cooling water distribution chamber to receive heated water from or supply cooling water to the cooling water distribution chamber at a location distal from the first water port, wherein the water channel extends to each of the second and third water ports.

2. The water cooling block of claim 1, wherein the cover further comprises on its inner surface converging channels arranged adjacent the first water port and adapted to flatten a stream of cooling water supplied from the first water port for distribution to the cooling water distribution chamber across the one side.

3. The water cooling block of claim 2, wherein the converging channels extend from the central location towards, but are not in fluid communication with, the second and third water ports.

4. The water cooling block of claim 2, wherein the converging channels flatten the stream of cooling water to a height from about 1 mm to about 5 mm, to a height from about 1 mm to about 3 mm, or to a height of about 1.5 mm.

5. The water cooling block of claim 1, wherein the microfins have a rectangular or triangular cross section.

6. The water cooling block of claim 1, wherein the microfins are lanced fins that have an opening in their cross section.

7. The water cooling block of claim 1, wherein the microfins are arranged in parallel rows in at least one direction.

8. The water cooling block of claim 1, wherein the microfins are arranged in parallel rows in two directions which are at 90 degree angles from one another.

9. The water cooling block of claim 1, wherein the microfins are arranged in an offset manner in another direction.

10. The water cooling block of claim 1, wherein the baseplate and the cover are rectangular in shape.

11. The water cooling block of claim 10, wherein the water channel extends in a C-shape between the second and third water ports.

12. The water cooling block of claim 1, wherein the water channel has a vertical height greater than the vertical height of the cooling water distribution chamber.

13. The water cooling block of claim 1, wherein the water cooling block is provided with a plurality of mounting holes extending from the top plate through the baseplate.

14. The water cooling block of claim 1, wherein the water channel is in fluid communication with a side of the cooling water distribution chamber at the location distal from the first water port and is not in fluid communication with the cooling water distribution chamber on other sides of the cooling water distribution chamber.

15. A cryptocurrency mining device comprising a hashboard having a plurality of application-specific integrated circuits mounted thereon, and the water cooling block of claim 1 mounted on the hashboard with the plurality of raised surfaces in contact with the integrated circuits.

16. A method of cooling the cryptocurrency mining device of claim 15, comprising supplying cooling water to the first water port and removing heated water from the second and third water ports.

17. A method of cooling the cryptocurrency mining device of claim 15, comprising supplying cooling water to the second and third water ports and removing heated water from the first water port.

18. The method of claim 17, comprising an additional step of supplying cooling air to the to the first water port and removing heated air from the second and third water ports.
